(19) United States
(12) Patent Application Publication
(10) Pub. No.: US 2025/0251234 A1
(43) Pub. Date: Aug. 7, 2025

(54) SELF-MIXING INTERFEROMETRY OPTO-ACOUSTIC TRANSDUCER AND METHOD OF OPERATING A SELF-MIXING INTERFEROMETRY

(71) Applicant: ams International AG, Jona (CH)

(72) Inventor: Jens HOFRICHTER, Horgen (CH)

(21) Appl. No.: 18/854,978

(22) PCT Filed: Apr. 12, 2023
(86) PCT No.: PCT/EP2023/059555

§ 371 Date: Oct. 8, 2024

(30) Foreign Application Priority Data
Apr. 20, 2022 (DE) 10 2022 109 537.1

(51) Int. Cl. G01B 9/02; G01B 9/02015; H01S 5/183; H04R 23/00

(52) U.S. Cl. CPC G01B 9/02092; G01B 9/02027; H01S 5/183; H04R 23/008; H04R 2201/003

(57) ABSTRACT

A self-mixing interferometry opto-acoustic transducer comprises a laser configured to perform two-sided emission through a first emission surface and a second emission surface, and to undergo self-mixing interference in a laser cavity of the laser, a diaphragm spaced away from the first emission surface of the laser, a photosensitive element arranged at or spaced away from the second emission surface of the laser, and structures arranged on the first emission surface or on a reflecting surface of the diaphragm facing the first emission surface. A first optical path is formed between the first emission surface and the reflecting surface, the first optical path including the structures, and a second optical path is formed between the first emission surface and the diaphragm, the second optical path including voids between the structures.

### RELATED APPLICATIONS

This patent application is a US National Stage application, filed under 35 U.S.C. § 371, of International Application PCT/EP2023/059555, filed on Apr. 12, 2023, and claims priority under 35 U.S.C. § 119 (a) and 35 U.S.C. § 365 (b) from German patent application 10 2022 109 537.1, filed Apr. 20, 2022, the contents of the above applications are hereby incorporated by reference.

### FIELD

Various embodiments of the present disclosure relate to a self-mixing interferometry, SMI, opto-acoustic transducer, an optical microphone assembly comprising such a transducer, and to a method of operating an SMI opto-acoustic transducer.

### BACKGROUND

Micro-electro-mechanical systems, MEMS, transducers for sensing dynamic pressure changes are used in a wide range of applications in modern consumer electronics, in particular as microphones for sensing pressure waves in the acoustic frequency band. Common examples in which highly integrated MEMS microphones play an important role are portable computing devices such as laptops, notebooks and tablet computers, but also portable communication devices like smart phones or smart watches. While modern transducers commonly rely on a capacitive readout, which is sufficient for example for high-end audio applications, emerging applications such as voice recognition and machine learning applications require an increased signal-to-noise ratio, SNR, beyond the capabilities of present capacitive transducers.

This requirement is met in state-of-the-art transducers by means of optically detecting a displacement or vibration of a MEMS diaphragm. In addition to a simple optical beam deflection scheme also known from atomic force microscopy, for even higher SNR modern opto-acoustic transducers employ optical interferometers, e.g., Mach-Zehnder or self-mixing interferometers. Therein, the latter approach realizes extremely compact solutions with a performance high enough for most everyday applications. However, the high sensitivity and compactness of an SMI readout scheme comes with the disadvantage of a limited dynamic range due to the optical properties of a single-mode self-mixing interferometric setup.

A first approach to overcome this limitation is to use a MEMS diaphragm with a very high stiffness in order to minimize the total displacement of the diaphragm. This approach, however, significantly compromises the overall noise performance of the optical microphone. A second approach relies on optically tuning the optical readout wavelength in order to dynamically operate the interferometer in a preferred regime. Downsides of this solution are the additional required tuning circuitry and a typically poor power efficiency due to the tuning mechanism, which is often based on adjusting a temperature operating point of the light emitter. A third approach of a Mach-Zehnder interferometric readout comes at the expense of substantial amounts of photonic circuitry required to realize said readout scheme.

Thus, various embodiments of the present disclosure relate to an opto-acoustic transducer with increased dynamic range that overcomes the limitations of existing solutions. Some embodiments relate to an optical microphone assembly and an electronic device comprising such a transducer and a method of operating an opto-acoustic transducer.

### SUMMARY

The improved concept is based on the idea of providing a dual optical mode self-mixing interference transducer, in which a displacement or vibration of a MEMS diaphragm can be detected via two optical modes selectively or concurrently, wherein the two optical modes are shifted by a fraction of the optical wavelength with respect to each other. This way, the typical limitation of the dynamic range of ±λ/4, with λ denoting the optical wavelength of the readout mode, can be overcome by means of a second optical mode, which, for example, is shifted by λ/4 with respect to the first optical mode. The readout is realized by means of an optical detector that is capable of distinguishing the two optical modes. In particular, the improved concept employs a self-mixing interferometer, thus alleviating the need for expensive real estate on a photonic die as it is the case for other types of interferometers, while owing to the dual mode operation passively achieving an increased dynamic range resulting in very little additional power overhead. Specifically, no power hungry current scanning technique to thermally tune the laser wavelength; or slow closed-loop operation as employed in current approaches is needed.

In an embodiment, a self-mixing interferometry, SMI, opto-acoustic transducer comprises a laser, a diaphragm and a photosensitive element. The laser is configured to perform two-sided emission through a first emission surface and a second emission surface opposite the first emission surface, and to undergo self-mixing interference in a laser cavity of the laser. The diaphragm is arranged spaced away from the first emission surface of the laser. The photo-sensitive element is arranged at or spaced away from the second emission surface of the laser. Moreover, the opto-acoustic transducer comprises structures that are arranged on the first emission surface or on a reflecting surface of the diaphragm facing the first emission surface.

Therein, a first optical path is formed between the first emission surface and the reflecting surface, the first optical path including the structures. A second optical path is formed between the first emission surface and the diaphragm, the second optical path including voids between the structures. The laser cavity and the first optical path form a first optical cavity supporting a first optical mode and the laser cavity and the second optical path form a second optical cavity supporting a second optical mode different from the first optical mode. Furthermore, the photosensitive element is configured to generate a first photo signal based on incident radiation at a first wavelength corresponding to the first optical mode and a second photo signal based on incident radiation at a second wavelength corresponding to the second optical mode.

The laser, for example, has a vertical laser cavity and emits electromagnetic radiation through partially transmissive end mirrors, e.g., Bragg mirrors, arranged on top and bottom sides of the laser cavity. The laser can be arranged on a substrate, e.g., a CMOS silicon die, such that a bottom side of the laser, i.e., the second emission surface, is parallel to and faces the substrate. The substrate can comprise laser contacts for electrically connecting the laser to a laser driver, and a photosensitive element that is arranged on a substrate surface or integrated within the substrate as an embedded photodetector, for instance. Therein, a photosensitive surface of the photosensitive element faces said bottom emission surface of the laser and can thus receive electromagnetic radiation that is emitted by the laser through the bottom emission surface. The photosensitive element can be arranged distant from the bottom emission surface or it is in contact with the latter.

The diaphragm, e.g., a MEMS membrane, is arranged on a side of the laser opposite the substrate, i.e., the diaphragm is arranged distant from the first, i.e., top emission surface of the laser such that a displacement of the diaphragm due to dynamic pressure changes, e.g., sound waves, alters a gap in between the laser and the diaphragm. In other words, a displacement of the diaphragm alters path lengths of the first and second optical paths. For example, the diaphragm is part of a MEMS die that is bonded to the substrate via spacers, for instance. The diaphragm has a reflective surface, e.g. a bottom surface of the diaphragm, which faces the top emission surface and can thus receive electromagnetic radiation that is emitted by the laser through the top emission surface. Therein, at least a portion of the electromagnetic radiation received from the laser is reflected off the reflective surface and directed back towards the top emission surface. At least a portion of this reflected electromagnetic radiation is coupled via the top emission surface back into the laser cavity causing the self-mixing interference.

Self-mixing interference in turn causes an alteration, e.g., modulation, of the optical power in the laser cavity and thus of the laser output power through both the first and second emission surfaces. Hence, the photosensitive element can detect the signatures of self-mixing interference caused by back reflections through the top emission surface due to a movement of the diaphragm. For distinguishing the two optical modes, the photosensitive element can comprise multiple channels, each equipped with a filter, for example, such that only light of the respective mode is detected by said channel.

The structures can realize a periodic pattern on the first emission surface or on the reflecting surface of the diaphragm, thus realizing a structured or patterned surface. In other words, the structures are arranged distant from each other such that gaps or voids in between are free of the structures. The structures are arranged such that they are exposed to electromagnetic radiation emitted by the laser through the first emission surface. This way, the structures alter an optical path between the laser and the diaphragm. Light that impinges onto or passes through the structures experiences an optical path with a different effective path length compared to light that impinges onto the diaphragm without impinging or passing through the structures, e.g. light that propagates in between the structures.

The structures hence lead to the fact that two different optical paths are formed such that the self-mixing interferometer formed from the laser cavity and the optical path between the first emission surface and the diaphragm supports two different optical modes that are shifted with respect to each other in terms of their wavelength. This way, when the dynamic range of one of the optical modes is exhausted due to substantial displacement of the diaphragm, the other optical mode can be used thus extending the dynamic range passively without any active tuning of the laser output wavelength of a single optical mode. Thus, the dynamic range is increased purely using optical means.

In some embodiments, the second wavelength differs from the first wavelength by a quarter of the first wavelength. A typical lasing wavelength of conventional opto-acoustic transducers is 940 nm, where assuming free-space propagation in vacuum, the maximum reflection of the membrane or diaphragm is limited to a quarter of this wavelength, i.e. to ±235 nm in this example. Further assuming a typical membrane stiffness of 10 nm/Pa, this results in a dynamic range of ±23.5 Pa, which correlates to an acoustic overload point (AOP) of only slightly above 120 dB sound-pressure level (SPL). However, the acoustic overload point is typically defined as 135 dB SPL, which is about 15 dB above the dynamic range of the currently pursued concept using a single fundamental mode in a self-mixing interferometry (SMI) based opto-acoustic transducer system. Hence, introducing a second optical mode that is shifted by a quarter wavelength from the first optical mode enables the system to switch to this second optical mode for reading out a displacement of the diaphragm, thus principally extending the dynamic range infinitely.

In some embodiments, the second optical mode differs from the first optical mode in terms of polarization. For example, the first optical mode is characterized by an s-type polarization, while the second optical mode is characterized by a p-type polarization. This way, the photosensitive element can employ a polarization filter to distinguish light that is captured at the wavelength corresponding to the first optical mode, and light that is captured at the wavelength corresponding to the second optical mode.

In some embodiments, the structures are formed from an electromagnetic metamaterial. An electromagnetic metamaterial affects electromagnetic waves that impinge on or interact with its structural features, which are smaller than the wavelength. Thus, photonic metamaterials are structured on the nanometer scale and manipulate light at optical frequencies. Thus the first optical path, on which light propagates through the metamaterial structures, can be engineered to have a different optical path length compared to the second optical path that propagates without passing through or impinging on the metamaterial structures.

In some embodiments, the diaphragm comprises a mirror layer arranged on a surface of the diaphragm facing the laser, the reflecting surface being a surface of the mirror layer facing the laser. In order to render at least a portion of the diaphragm surface facing the laser reflective, a mirror layer, e.g. formed from a metal, can be arranged on said surface of the diaphragm, thus defining the reflective surface. The mirror layer is arranged such that the light from the laser impinges onto the mirror layer and is at least partially reflected back towards the first emission surface.

In some embodiments, the structures are arranged on the surface of the mirror layer and are formed from a material of the mirror layer. In order to effectively shorten the path length of the first optical path, the surface of the mirror layer can be structured such that a portion of the light from the laser is reflected back from the structures, while the remaining portion of the light is reflected back from the mirror layer in places, in which no structures are arranged on the mirror layer. For example, the mirror layer and the structures are formed from a metal that is reflective at an emission wavelength of the laser. For a shift of the first optical mode of a quarter wavelength with respect to the second optical mode, a thickness of the structures measured from the surface of the mirror layer can be an eighth of the optical wavelength of the first optical mode, thus shortening the first optical path by a quarter wavelength due to the double pass of light owing to the reflection.

In some embodiments, the opto-acoustic transducer further comprises a lens element arranged on the first emission surface or the reflecting surface. For further directing light towards the reflective surface and/or reinjecting reflected light back into the laser cavity, a lens element can be arranged on the first and second optical paths such that all light from the laser passes through the lens element a first tie after emission through the first emission surface and a second time after reflection off of the reflective surface.

In some embodiments, the structures are embedded within the lens element. Embedding the structures into the lens element means that both components can be arranged on the same surface, i.e., the reflective surface of the diaphragm or the first emission surface of the laser. Thus, the lens element surrounding the structures can act as a protective cap.

In some embodiments, the structures form a diffractive pattern. Instead of a dedicated lens element, in alternative embodiments the structures themselves are designed to not only alter an optical path for the first optical mode, but also can be designed to focus light that is passing through the structured pattern created by the structures back into the laser cavity and/or collimate emitted light from the laser onto the reflective surface of the diaphragm.

In some embodiments, the structures are polarizing structures configured to alter a polarization of light passing through the structures. Optical cavities of a certain length typically support optical modes of different polarization. Thus, designing the structures to alter the polarization direction of light on the first optical path can lead to an optical mode that is different from that on the second optical path that does not interact with the polarizing structures. For example, the structures form optical wave plates, in particular optical quarter-wave plates.

In some embodiments, the structures form a high contrast grating. A high contrast grating is formed by a single layer near-wavelength grating physical structure where the grating material has a large contrast in index of refraction with its surroundings. Therein, the grating period of the high contrast grating is between the optical wavelength in the grating material and that in its surrounding material. High contrast gratings can be characterized by an ultra-high reflectivity, transmission or wavelength filtering properties.

In some embodiments, the laser is a vertical cavity surface emitting laser, VCSEL, diode. VCSEL diodes are characterized by a beam emission that is perpendicular to a main extension plane of a top surface of the VCSEL. The VCSEL diode can be formed from semiconductor layers on a substrate, wherein the semiconductor layers comprise two distributed Bragg reflectors (DBR) enclosing active region layers in between and thus forming a cavity. VCSELs and their principle of operation are a well-known concept and are not further detailed throughout this disclosure. For example, the VCSEL diode is configured to have an emission wavelength of 940 nm, 850 nm, or another natural wavelength. The VCSEL diode can be configured to emit coherent laser light when forward biased, for instance. Suitable alternative light emitters include semiconductor lasers such as edge emitters, quantum cascade and quantum dots laser. In particular, the laser is a multimode laser.

In some embodiments, the photosensitive element comprises a high contrast grating. As described in U.S. Pat. No. 10,763,380 B2, for example, a photodetector having a high-contrast grating polarizer can be rendered sensitive only to a particular polarization of the incident light. Thus, particularly in embodiments, in which the first and second optical modes differ not only in terms of wavelength but also in terms of polarization, the photosensitive element can comprise two channels with different high contrast grating polarizers in order to distinguish the first optical mode and the second optical mode.

Furthermore, an optical microphone assembly is provided, wherein the assembly comprises a SMI opto-acoustic transducer according to one of the aforementioned embodiments, and a readout circuit that is configured to determine a displacement of the diaphragm based on the first photo signal and the second photo signal, and to generate an output signal based on the determined displacement.

In an embodiment, the optical microphone assembly further comprises an enclosure surrounding the SMI opto-acoustic transducer, the enclosure comprising at least one sound port opening.

Furthermore, an electronic device is provided, the electronic device comprising an optical microphone assembly according to one of the aforementioned embodiments, wherein the optical microphone assembly is configured to convert a sound wave into an electronic audio signal as the output signal.

Furthermore, a method of operating a self-mixing interferometry, SMI, opto-acoustic transducer, is provided. The method comprises providing a laser having a first emission surface and a second emission surface opposite the first emission surface, arranging a diaphragm spaced away from the first emission surface of the laser, and arranging a photosensitive element at or spaced away from the second emission surface. The method further comprises arranging structures on the first emission surface or a reflecting surface of the diaphragm facing the first emission surface such that a first optical path and a second optical path is formed between the first emission surface and the reflecting surface, the first optical path including the structures and the second optical path including voids between the structures.

The method further comprises two-sidedly emitting (TSE), by means of the laser, electromagnetic radiation through the first emission surface and the second emission surface, reinjecting electromagnetic radiation that is emitted through the first emission surface and reflected off the reflecting surface back into a laser cavity for generating self-mixing interference, and generating, by means of the photosensitive element, a first photo signal based on incident radiation at a first wavelength corresponding to a first optical mode and a second photo signal based on incident radiation at a second wavelength corresponding to a second optical mode.

Therein, the laser cavity and the first optical path form a first optical cavity supporting the first optical mode and the laser cavity and the second optical path form a second optical cavity supporting the second optical mode different from the first optical mode.

Further embodiments of the method become apparent to the skilled reader from the aforementioned embodiments of the SMI opto-acoustic transducer, the optical microphone assembly, and the electronic device, and vice-versa.

### BRIEF DESCRIPTION OF THE DRAWINGS

The following description of figures may further illustrate and explain aspects of the SMI opto-acoustic transducer and the method of operating an SMI opto-acoustic transducer. Components and parts of the opto-acoustic transducer that are functionally identical or have an identical effect are denoted by identical reference symbols. Identical or effectively identical components and parts might be described only with respect to the figures where they occur first. Their description is not necessarily repeated in successive figures.

In the figures:

FIG. 1 shows a microphone assembly comprising a first exemplary embodiment of an SMI opto-acoustic transducer according to the improved concept;

FIG. 2 shows a microphone assembly comprising a second exemplary embodiment of an SMI opto-acoustic transducer;

FIG. 3 shows a microphone assembly comprising a third exemplary embodiment of an SMI opto-acoustic transducer;

FIG. 4 shows a microphone assembly comprising a fourth exemplary embodiment of an SMI opto-acoustic transducer;

FIG. 5 shows a microphone assembly comprising a fifth exemplary embodiment of an SMI opto-acoustic transducer;

FIG. 6 shows a microphone assembly comprising a sixth exemplary embodiment of an SMI opto-acoustic transducer;

FIG. 7 shows an exemplary embodiment of an electronic device comprising a microphone assembly; and

FIG. 8 shows transmission characteristics of a dual-mode optical interferometer.

### DETAILED DESCRIPTION

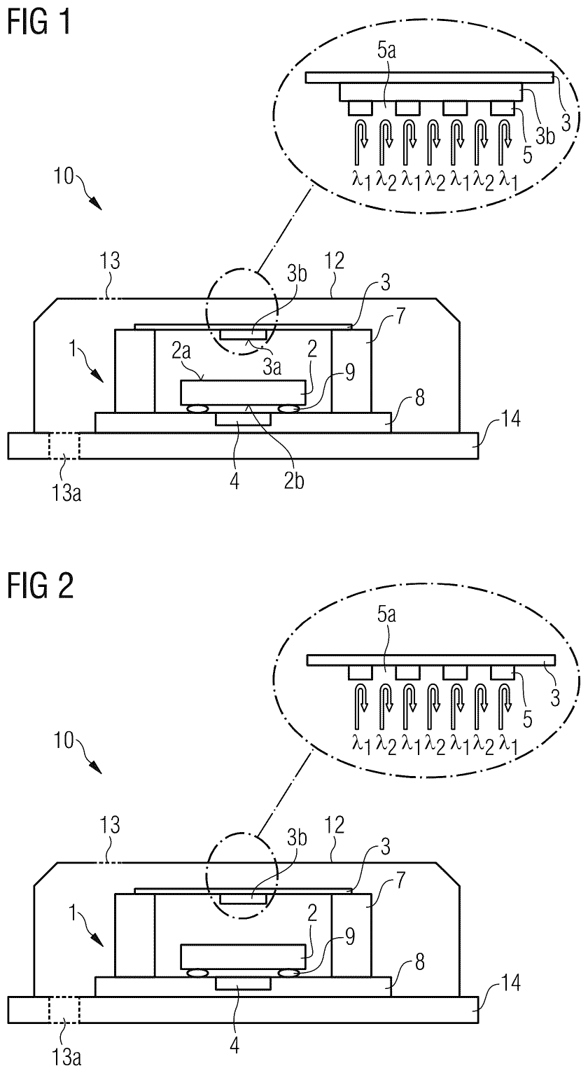

FIG. 1 shows a microphone assembly 10 comprising a first exemplary embodiment of an SMI opto-acoustic transducer 1 according to the improved concept. The opto-acoustic transducer 1 comprises a laser 2 that is arranged on an integrated circuit substrate 8. An electrical connection between the laser 2 and contacts of the integrated circuit substrate 8 is realized via connection elements 9, e.g., solder bumps formed from an electrically conductive material such as AgSN, Cu or Au, for instance. The laser 2 can be a vertical cavity surface emitting laser, VCSEL, and comprises a first emission surface 2a and a second emission surface 2b opposite the first emission surface 2a. The laser 2 further comprises a laser cavity. The emission surfaces 2a, 2b can be defined by partially transmissive end mirrors of the laser cavity, e.g. Bragg mirrors. Thus, the laser 2 is configured to emit light in a vertical direction through both the first and second emission surfaces 2a, 2b.

The integrated circuit substrate 8 comprises a photosensitive element 4, e.g. an embedded photodetector, which is configured to generate a first photo signal based on incident radiation at a first wavelength λ₁ and a second photo signal based on incident radiation at a second wavelength λ₂ corresponding to the second optical mode. For example, the photosensitive element 4 is realized by a multi-channel photodetector that can distinguish between electromagnetic radiation captured at at least two different wavelengths or wavelength ranges. The integrated circuit substrate 8 can comprise further circuitry for reading out the first and second photo signals, and for controlling an emission of the laser 2, for instance.

The opto-acoustic transducer 1 further comprises a diaphragm 3, e.g., a MEMS membrane, which is spaced away from the first emission surface 2a of the laser 2. In other words, the diaphragm 3 is suspended above the first emission surface 2a. For example, the diaphragm 3 is comprised by a MEMS die that is bonded to the integrated circuit substrate 8 via spacers 7. Thus, a principle direction of deflection of the diaphragm 3 is parallel to an emission direction of the laser 2, such that a deflection of the diaphragm 3 changes a gap distance between the diaphragm 3 and the first emission surface 2a of the laser 2. The diaphragm 3 comprises a reflecting surface 3a, which may be a surface of the diaphragm 3 itself or a surface of a mirror layer 3b that is arranged on the bottom side of the diaphragm 3 facing the laser 2. The latter case is illustrated in FIG. 1, wherein the mirror layer 3b is formed from a metal that is reflective at an emission wavelength of the laser 2. The reflecting surface 3a ensures that light from the laser 2, which impinges on the reflecting surface 3a, is directed back towards the first emission surface 2a for reinjection of the reflected light into the laser cavity.

As illustrated in the magnified view of the diaphragm 3, structures 5 are arranged on the reflecting surface 3a of the mirror layer 3b in a manner that some portions of the reflecting surface 3a are covered by the structures 5, while remaining portions are free of the structures 5. In other words, the structures 5 are arranged on the reflecting surface 3a such that voids 5a are formed in between the structures. For example, the structures 5 and voids 5a realize a periodic pattern on the reflecting surface 3a. For example, the structures cover half of the reflecting surface 3a at least in an area that is exposed to light emitted by the laser 2. Therein, the structures 5 are designed in a way that light that impinges on or passes through the structures 5 experiences an effective optical path length that is different from the path length for the light that is directed towards the reflecting surface 3a without impinging on or passing through the structures 5, i.e., impinging on the reflecting surface 3a within the voids 5a. This means that two optical cavities are formed, wherein a first optical cavity comprises the laser cavity and the gap between the first emission surface 2a and the reflecting surface 3a in places, in which structures 5 are present, and a second optical cavity comprises the laser cavity and the gap between the first emission surface 2a and the reflecting surface 3a in places, in which voids 5a between the structures 5 are present.

The first optical cavity supports a first optical mode characterized by the first optical wavelength λ₁ and the second optical cavity supports a second optical mode characterized by the second optical wavelength λ₂ that is different from the first wavelength λ₁. For example, the second wavelength λ₂ differs from the first wavelength λ₁ by a quarter of the first wavelength λ₁, or vice versa. A shift by a quarter wavelength is ideal, as a maximum cavity transmission power is achieved for the second optical mode, when the cavity transmission power of the first optical modes vanishes at a quarter wavelength detuning. Specifically, in a conventional single-mode opto-acoustic transducer, a typical lasing wavelength is 940 nm, where assuming free-space propagation in vacuum, the maximum reflection of the membrane or diaphragm is limited to a quarter of the wavelength, or ±235 nm in this example. Assuming a typical membrane stiffness of 10 nm/Pa, this results in a dynamic range of ±23.5 Pa, which correlates to an acoustic overload point (AOP) of only slightly above 120 dB sound-pressure level (SPL). However, the acoustic overload point is typically defined as 135 db SPL, which is about 15 dB above the dynamic range.

To enable formation of a second fundamental optical mode, the structures 5 can be formed from a material of the mirror layer 3b in order to provide an actually shortened path for light on that respective optical path. Alternatively, the structures 5 can be formed from an electromagnetic metamaterial that is characterized by different optical properties compared to a medium between the laser and the diaphragm and inside the voids 5a, e.g. a gas such as air, or vacuum. For example, the structures 5 formed from an electromagnetic metamaterial are characterized by a negative index of refraction.

As the light is reflected off the reflective surface 3a of the diaphragm 3 and reinjected into the laser cavity of the laser via the first emission surface 2a, self-mixing interference forms within the laser cavity, thus influencing the output optical power of the laser 2. As the laser 2 is configured to perform dual-side emission, i.e., it emits light of the same optical modes through the first and second emission surfaces 2a, 2b, these alterations, e.g., modulations, of the laser output power of the respective optical modes can be detected by the photosensitive element 4 that is arranged such that a photoactive surface faces the second emission surface 2b of the laser 2. Since the photosensitive element 4 is configured to distinguish between the two optical modes, i.e., generate respective first and second photo signals, a displacement of the diaphragm 3 can be determined by evaluating one of the two photo signals, wherein one photo signal has its maximum value when the respective other photo signal vanishes due to a suppression of the associated optical mode in the case of the two wavelengths λ₁, λ₂ being shifted by a quarter wavelength.

For forming a microphone assembly 10, the opto-acoustic transducer 1 is arranged on a substrate 14, e.g. a PCB board, and enclosed by an enclosure 12, which is a metal cap, for instance. As sound inlet, the substrate 14 and/or the enclosure 12 comprises a sound port 13 for allowing dynamic pressure changes to actuate on the diaphragm.

FIG. 2 shows a microphone assembly 10 comprising a second exemplary embodiment of an SMI opto-acoustic transducer 1. Compared to the first embodiment, the diaphragm 3 in this embodiment is free of any mirror layer 3b such that the structures 5 are arranged directly on a surface of the diaphragm 3. For example, the diaphragm itself is formed from a material that is reflective for light emitted by the laser 2, such that a dedicated mirror layer 3b can be omitted, or the structures 5 form an arrangement that enables the reflection of light. Specifically, the structures 5 can be arranged to realize a high contrast optical grating. Therein, by locally changing a grating dimension across the reflecting surface 3a, the support of different optical modes can be enabled.

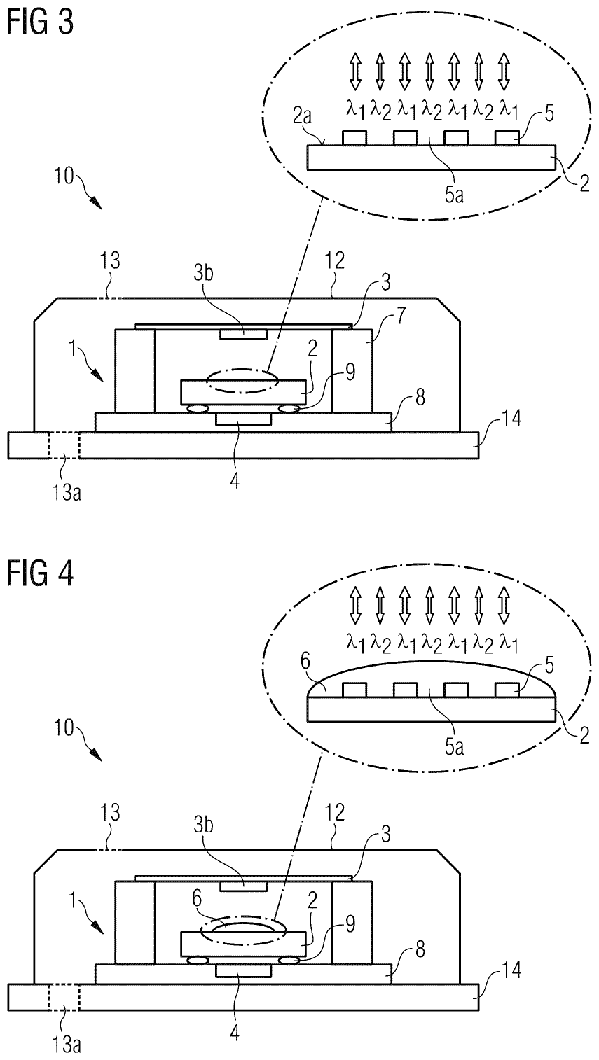

FIG. 3 shows a microphone assembly 10 comprising a third exemplary embodiment of an SMI opto-acoustic transducer 1. Compared to the first and second embodiments, structures 5 in this embodiment are arranged on the first emission surface 2a of the laser 2 for defining the first and second optical modes. Like in the previous embodiments, the structures 5 can be formed from an electromagnetic metamaterial and realize a high contrast optical grating. In addition, the structures 5 can further realize a diffractive mechanism, in which light from the laser 2 is collimated or focused towards the reflective surface 3a of the diaphragm 3, and focused back into the laser cavity on the return path after reflecting off the diaphragm 4.

FIG. 4 shows a microphone assembly 10 comprising a fourth exemplary embodiment of an SMI opto-acoustic transducer 1. Compared to the third embodiment, the opto-acoustic transducer 1 in this embodiment further comprises a lens element 6, wherein the structures 5 on the first emission surface 2a are embedded within the lens element 6 as illustrated. Thus, also with the structures not realizing a diffractive mechanism themselves, an additional lens element 6 can serve the purpose of directing the light from the laser 2 to the reflective surface 3a of the diaphragm 3 and reinjecting the reflected light back into the laser cavity on the return path.

FIG. 5 shows a microphone assembly 10 comprising a fifth exemplary embodiment of an SMI opto-acoustic transducer 1. This fifth embodiment is similar to the first embodiment of FIG. 1 with the addition that the structures 5 in this embodiment alter a polarization of the light passing through the structures 5. For example, the laser 2 emits light of a first polarization, e.g. p-type polarization. Light that is reflected from the reflective surface 3a, in this case a surface of the mirror layer 3b, without passing through the structures 5, i.e. propagating through the voids 5a, maintains this first polarization, while light that passes through the structures 5 is altered in its polarization such that light on this optical path has a second type of polarization, e.g. s-type polarization, when being reinjected into the laser cavity. For example, the structures 5 realize quarter-wave plates, which due to the double-pass configuration, rotate and transform the polarization direction between p- and s-type polarizations.

Accordingly, the photosensitive element 4 can likewise be configured to distinguish between the first and second type of polarization in order to generate the first photo signal based on the first optical mode, and the second photo signal based on the second optical mode. For example, the photosensitive element 4 can be a multi-channel photodetector, wherein each channel comprises a high contrast grating likewise formed from polarizing structures 5 arranged on an active surface of the photosensitive element 4.

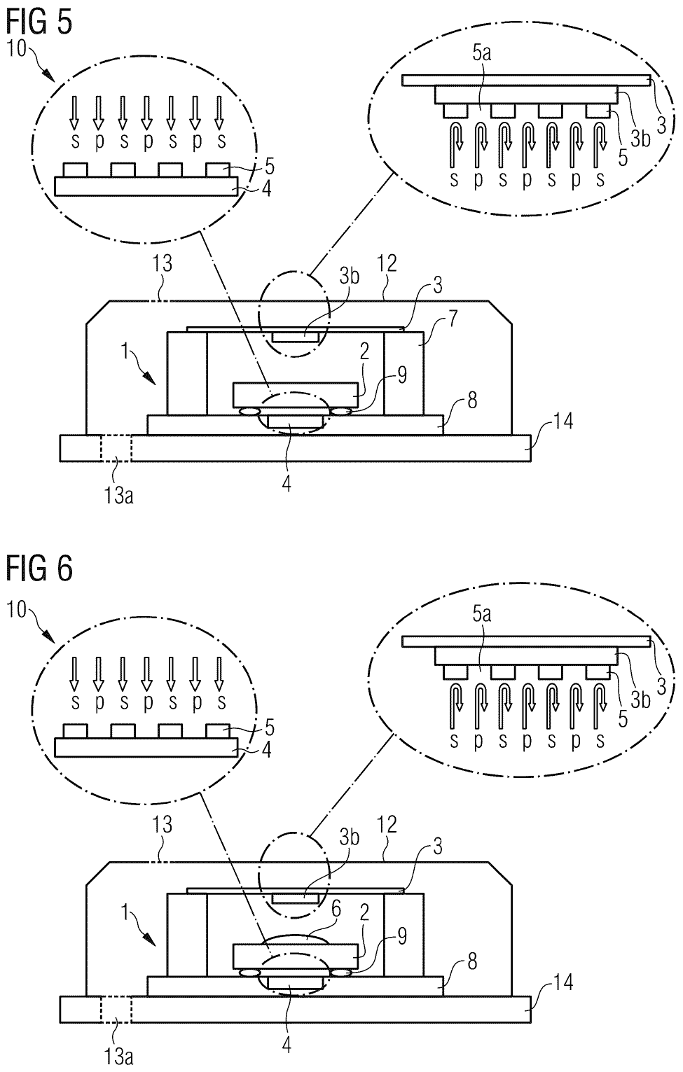

FIG. 6 shows a microphone assembly 10 comprising a sixth exemplary embodiment of an SMI opto-acoustic transducer 1. This sixth embodiment combines the fifth embodiment of FIG. 5 with the additional lens element 6 of the fourth embodiment. The lens element can likewise serve the purpose of directing, collimating and focusing light towards the diaphragm 3 and back into the laser cavity on the return path after reflection.

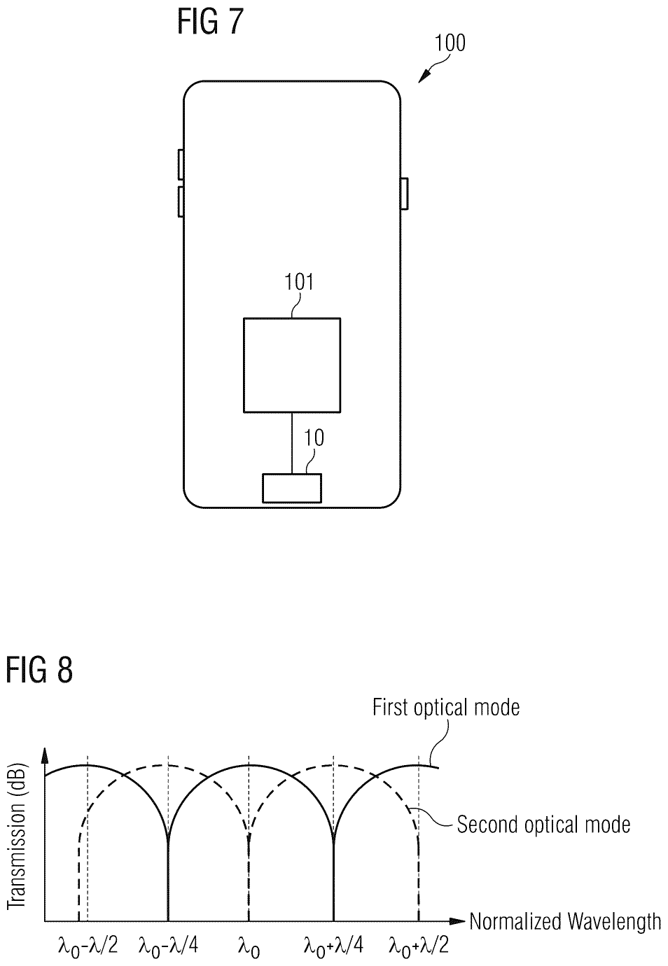

FIG. 7 shows an exemplary embodiment of an electronic device 100 comprising a microphone assembly 10 according to one of the embodiments described above. The electronic device 100 can be a smartphone, a tablet or laptop computer, a media player, a wearable device or any other electronic device employing a microphone for converting sound into electronic audio signals. The electronic device 100 further comprises a processing unit 101 that is electrically coupled to the microphone assembly 10 such that the former can receive the first and second photo signals or a signal derived from the first and second photo signals for further processing.

FIG. 8 shows exemplary transmission characteristics of a dual mode SMI opto-acoustic transducer 1 according to the improved concept, wherein the first and second optical modes are shifted in terms of their wavelength by a quarter of the optical wavelength. Thus, as illustrated, while the cavity transmission of the first optical mode vanishes at a detuning of λ/4, tantamount to a deflection of the reflecting surface 3a of the diaphragm 3 by a quarter of the wavelength in either direction, the second mode has their transmission maximum at this point, and vice versa. Thus, the dynamic range is arbitrarily increased using two optical modes that are shifted by a quarter wavelength.

The embodiments of the SMI opto-acoustic transducer 1, the microphone assembly 10 and the method of operating an SMI opto-acoustic transducer disclosed herein have been discussed for the purpose of familiarizing the reader with novel aspects of the idea. Although some embodiments have been shown and described, changes, modifications, equivalents and substitutions of the disclosed concepts may be made by one having skill in the art without unnecessarily departing from the scope of the claims.

It will be appreciated that the disclosure is not limited to the disclosed embodiments and to what has been particularly shown and described hereinabove. Rather, features recited in separate dependent claims or in the description may advantageously be combined. Furthermore, the scope of the disclosure includes those variations and modifications, which will be apparent to those skilled in the art and fall within the scope of the appended claims.

The term “comprising”, insofar it was used in the claims or in the description, does not exclude other elements or steps of a corresponding feature or procedure. In case that the terms “a” or “an” were used in conjunction with features, they do not exclude a plurality of such features. Moreover, any reference signs in the claims should not be construed as limiting the scope.

### REFERENCES

1 self-mixing interference opto-acoustic transducer
2 laser
2a, 2b emission surface
3 diaphragm
3a reflective surface
3b mirror layer
4 photosensitive element
5 structure
5a void
6 lens element
7 spacer
8 integrated circuit substrate
9 connection element
10 microphone assembly
11 readout circuit
12 enclosure
13 sound port
14 substrate
100 electronic device
101 processing unit

What is claimed is:

1. A self-mixing interferometry, SMI, opto-acoustic transducer, comprising:
a laser configured to perform two-sided emission through a first emission surface and a second emission surface opposite the first emission surface, and configured to undergo self-mixing interference in a laser cavity of the laser;
a diaphragm spaced away from the first emission surface of the laser, wherein the diaphragm comprises a reflecting surface facing the first emission surface;
a photosensitive element arranged at or spaced away from the second emission surface of the laser; and
structures arranged on the first emission surface or on the reflecting surface of the diaphragm;
wherein a first optical path is formed between the first emission surface and the reflecting surface, the first optical path including the structures;
wherein a second optical path is formed between the first emission surface and the diaphragm, the second optical path including voids between the structures;
wherein the laser cavity and the first optical path form a first optical cavity supporting a first optical mode and the laser cavity and the second optical path form a second optical cavity supporting a second optical mode different from the first optical mode; and
wherein the photosensitive element is configured to generate a first photo signal based on incident radiation at a first wavelength corresponding to the first optical mode and a second photo signal based on incident radiation at a second wavelength corresponding to the second optical mode.

2. The SMI opto-acoustic transducer according to claim 1, wherein the second wavelength differs from the first wavelength by a quarter of the first wavelength.

3. The SMI opto-acoustic transducer according to claim 1, wherein the second optical mode differs from the first optical mode in terms of polarization.

4. The SMI opto-acoustic transducer according to claim 1, wherein the structures are formed from an electromagnetic metamaterial.

5. The SMI opto-acoustic transducer according to claim 1, wherein the diaphragm comprises a mirror layer arranged on a surface of the diaphragm facing the laser, the reflecting surface being a surface of the mirror layer facing the laser.

6. The SMI opto-acoustic transducer according to claim 5, wherein the structures are arranged on the surface of the mirror layer and are formed from a material of the mirror layer.

7. The SMI opto-acoustic transducer according to claim 1, further comprising a lens element arranged on the first emission surface or the reflecting surface.

8. The SMI opto-acoustic transducer according to claim 7, wherein the structures are embedded within the lens element.

9. The SMI opto-acoustic transducer according to claim 1, wherein the structures form a diffractive pattern.

10. The SMI opto-acoustic transducer according to claim 1, wherein the structures are polarizing structures configured to alter a polarization of light passing through the structures.

11. The SMI opto-acoustic transducer according to claim 10, wherein the structures form optical wave plates, in particular optical quarter-wave plates.

12. The SMI opto-acoustic transducer according to claim 1, wherein the structures form a high contrast grating.

13. The SMI opto-acoustic transducer according to claim 1, wherein the laser is a vertical cavity surface emitting laser, VCSEL.

14. The SMI opto-acoustic transducer according to claim 1, wherein the photosensitive element comprises a high contrast grating.

15. An optical microphone assembly, comprising:
a SMI opto-acoustic transducer according to claim 1; and
a readout circuit configured to determine a displacement of the diaphragm based on the first photo signal and the second photo signal, and to generate an output signal based on the determined displacement.

16. The optical microphone assembly according to claim 15, further comprising an enclosure surrounding the SMI opto-acoustic transducer, the enclosure comprising at least one sound port opening.

17. An electronic device comprising an optical microphone assembly according to claim 15, wherein the optical microphone assembly is configured to convert a sound wave into an electronic audio signal as the output signal.

18. A method of operating a self-mixing interferometry, SMI, opto-acoustic transducer, the method comprising:
providing a laser having a first emission surface and a second emission surface opposite the first emission surface;
arranging a diaphragm spaced away from the first emission surface of the laser, wherein the diaphragm comprises a reflecting surface facing the first emission surface;
arranging a photosensitive element at or spaced away from the second emission surface;
arranging structures on the first emission surface or a on the reflecting surface of the diaphragm such that a first optical path and a second optical path is formed between the first emission surface and the reflecting surface, the first optical path including the structures and the second optical path including voids between the structures;
two-sidedly emitting, by means of the laser, electromagnetic radiation through the first emission surface and the second emission surface;
reinjecting, back into a laser cavity, electromagnetic radiation that is emitted through the first emission surface and reflected off the reflecting surface for generating self-mixing interference; and
generating, by means of the photosensitive element, a first photo signal based on incident radiation at a first wavelength corresponding to a first optical mode and a second photo signal based on incident radiation at a second wavelength corresponding to a second optical mode;
wherein the laser cavity and the first optical path form a first optical cavity supporting the first optical mode and the laser cavity and the second optical path form a second optical cavity supporting the second optical mode different from the first optical mode.
